(19) United States
(12) Patent Application Publication
(10) Pub. No.: US 2024/0188369 A1
(43) Pub. Date: Jun. 6, 2024

(54) DISPLAY PANEL AND DISPLAY DEVICE

(71) Applicant: Shanghai Tianma Microelectronics Co., Ltd., Shanghai (CN)

(72) Inventor: Qijun YAO, Shanghai (CN)

(73) Assignee: Shanghai Tianma Microelectronics Co., Ltd., Shanghai (CN)

(21) Appl. No.: 18/409,021

(22) Filed: Jan. 10, 2024

(30) Foreign Application Priority Data
Mar. 31, 2023 (CN) 202310342802.X

(51) Int. Cl. H10K 59/38

(52) U.S. Cl. CPC H10K 59/38

(57) ABSTRACT

A display panel includes first-band color pixels and a color resist layer. One of the first-band color pixels includes at least two light-emitting devices emitting light of the same color. The color resist layer includes first-band light emission color resists corresponding to the first-band color pixels, where a first-band light emission color resist includes at least two sub-color resists transmitting light of different central wavelengths.

### CROSS-REFERENCE TO RELATED APPLICATION

This application claims priority to Chinese Patent Application No. 202310342802.X filed Mar. 31, 2023, the disclosure of which is incorporated herein by reference in its entirety.

### TECHNICAL FIELD

The present disclosure relates to the field of display technologies and, in particular, to a display panel and a display device.

### BACKGROUND

For light-emitting devices emitting light of the same color in a display panel in the related art, a display contrast is typically improved by color resists transmitting light of the same central wavelength. However, when multiple display requirements for transmitting light of different central wavelengths exist, different requirements cannot be satisfied.

### SUMMARY

Embodiments of the present disclosure provide a display panel and a display device. A first-band light emission color resist is configured to correspond to a first-band color pixel, where the first-band color pixel includes at least two light-emitting devices emitting light of the same color, and the first-band light emission color resist includes at least two sub-color resists transmitting light of different central wavelengths. Thus, according to different display requirements, corresponding light-emitting devices are controlled to emit light, thereby improving application scenarios of the display panel.

In an aspect, embodiments of the present disclosure provide a display panel. The display panel includes first-band color pixels and a color resist layer. One of the first-band color pixels includes at least two light-emitting devices emitting light of the same color.

The color resist layer includes first-band light emission color resists corresponding to the first-band color pixels, where a first-band light emission color resist includes at least two sub-color resists transmitting light of different central wavelengths.

In another aspect, embodiments of the present disclosure further provide a display device including the light-emitting panel described above.

### BRIEF DESCRIPTION OF DRAWINGS

FIG. 1 is a structural diagram of a display panel according to an embodiment of the present disclosure;

FIG. 2 is a sectional view along AA′ in FIG. 1;

FIG. 3 is another sectional view along AA′ in FIG. 1;

FIG. 4 is another sectional view along AA′ in FIG. 1;

FIG. 5 is another sectional view along AA′ in FIG. 1;

FIG. 6 is another sectional view along AA′ in FIG. 1;

FIG. 7 is a structural diagram of another display panel according to an embodiment of the present disclosure;

FIG. 8 is a structural diagram of another display panel according to an embodiment of the present disclosure;

FIG. 9 is a structural diagram of another display panel according to an embodiment of the present disclosure;

FIG. 10 is a circuit diagram of a pixel circuit according to an embodiment of the present disclosure;

FIG. 11 is a structural diagram of another display panel according to an embodiment of the present disclosure; and

FIG. 12 is a structural diagram of a display device according to an embodiment of the present disclosure.

### DETAILED DESCRIPTION

In order that solutions in embodiments of the present disclosure or the related art are described more clearly, drawings to be used in the description of the embodiments or the related art are briefly described hereinafter. Apparently, while the drawings in the description hereinafter are some embodiments of the present disclosure, for those skilled in the art, these drawings may be expanded and extended to other structures and drawings according to the basic concepts of the device structure, driving method, and manufacturing method disclosed and indicated in embodiments of the present disclosure. These are undoubtedly all within the scope of the claims of the present disclosure.

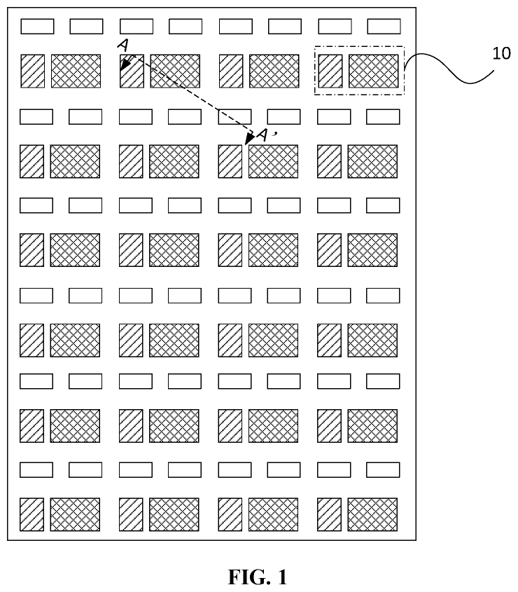

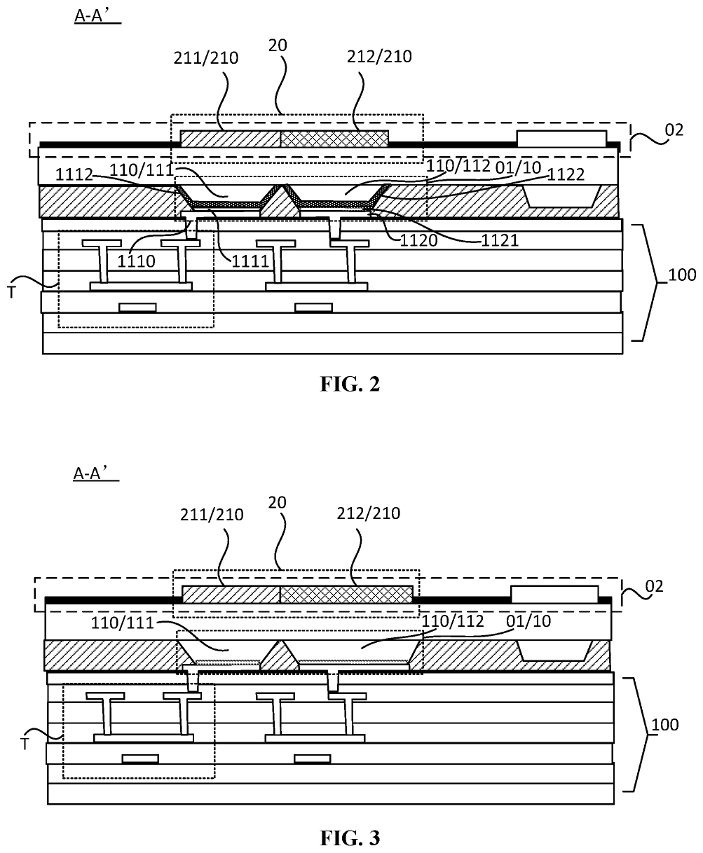

FIG. 1 is a structural diagram of a display panel according to an embodiment of the present disclosure. FIG. 2 is a sectional view along AA′ in FIG. 1. Referring to FIGS. 1 and 2, the display panel includes first-band color pixels 10 and the color resist layer 02, where one first-band color pixel 10 includes at least two light-emitting devices 110 emitting light of the same color; and the color resist layer 02 includes first-band light emission color resists 20 corresponding to the first-band color pixels 10, where a first-band light emission color resist 20 includes at least two sub-color resists 210 transmitting light of different central wavelengths.

Specifically, as shown in FIGS. 1 and 2, the display panel includes an array substrate 100 and sub-pixels 01 disposed on the array substrate 100. The array substrate 100 may be a low-temperature polycrystalline silicon array substrate, an indium gallium zinc oxide (IGZO) array substrate, or other types of substrates having thin-film transistor (TFT) arrays. Multiple driver circuits (not shown) configured to drive the sub-pixels 01 are disposed in the array substrate 100, and each driver circuit includes at least one TFT T driving a sub-pixel 01 to emit light. The structure of the TFT T may be a top-gate structure or a bottom-gate structure. The structure of the TFT is not limited here. For example, if the structure of the TFT T is the bottom-gate structure, the array substrate 100 may include a buffer layer, a gate metal layer, a first insulating layer, an active layer, a second insulating layer, and a source/drain metal layer which are stacked sequentially, where the channel of the transistor is disposed in the active layer, the gate of the transistor is disposed in the gate metal layer, and the source and drain of the transistor are disposed in the source/drain metal layer. It is to be noted that the specific structure of a pixel driving circuit is not limited in the embodiments of the present disclosure. The pixel driving circuit may include two transistors and one storage capacitor, that is, a “2TIC” driver circuit, or the pixel driving circuit may include seven transistors and one storage capacitor, that is, a “7TIC” driver circuit as long as the sub-pixels 01 may be normally driven to emit light and perform a display.

The sub-pixel 01 includes an anode, a light-emitting functional layer, and a cathode disposed sequentially facing a side of the array substrate 100. The drain of the TFT T is connected to the anode. In addition, the light-emitting functional layer may be a laminate including a hole injection layer, a hole transport layer, a light-emitting layer, an electron transport layer, and an electron injection layer which are stacked. Specifically, when no voltage is applied to the anode and the cathode, the sub-pixel 01 does not emit the light, and when a voltage is applied to the anode and the cathode, the anode injects holes into the hole injection layer, the cathode injects electrons into the electron injection layer, and the holes and the electrons recombine to form light excitons in the light-emitting layer to emit the light through radiation.

The display panel further includes the color resist layer 02 disposed on the side of the sub-pixel 01 facing away from the array substrate 100, that is, the color resist layer 02 is disposed on the light emission side of the sub-pixel 01. The color resist layer 02 includes multiple light emission color resists of different colors. Further, with the light emission color resists, light emitted at the sub-pixel 01 whose emitted color is a first color passes through the light emission color resists and can keep having the first color, and after ambient light passes through the light emission color resists, enters the display panel, and is reflected in each film of the display panel, the light emission color resists can filter out light of other colors in the reflected light and only the light of the first color in the reflected light is transmitted. Thus, the ambient light can be prevented from influencing the light emission accuracy of the sub-pixel 01. In the related art, for the sub-pixel 01 emitting the same color, a light emission color resist of the corresponding color is typically disposed to transmit light, and the light emission color resist can transmit light of the same central wavelength to improve a display contrast. However, when there is a display requirement that the light emission color resist of the corresponding color needs to transmit light of different central wavelengths, different display requirements cannot be met.

For this reason, in the embodiments of the present disclosure, the sub-pixel 01 is configured to include the first-band color pixel 10, the color resist layer 02 includes the first-band light emission color resists 20 corresponding to the first-band color pixels 10, and light emitted at the first-band color pixel 10 whose emitted color is a first-band color is transmitted by the first-band light emission color resist 20. The one first-band color pixel 10 includes the at least two light-emitting devices 110 emitting the light of the same color and the first-band light emission color resist 20 includes the at least two sub-color resists 210 transmitting the light of the different central wavelengths so that the two light-emitting devices 110 emitting the light of the same color may separately correspond to the two sub-color resists 210 transmitting the light of the different central wavelengths. Thus, according to the requirement of the first-band color pixel 10 in the display panel for transmitting the light of the different central wavelengths, the light-emitting devices 110 corresponding to the sub-color resists 210 transmitting the light of the central wavelengths may be controlled to emit the light, thereby satisfying different display requirements and improving application scenarios of the display plane.

In summary, in the display panel provided by the embodiments of the present disclosure, the one first-band color pixel is configured to include the at least two light-emitting devices emitting the light of the same color, the first-band light emission color resist is configured to include the at least two sub-color resists transmitting the light of the different central wavelengths, and the first-band color pixels are configured to correspond to the first-band light emission color resists, that is, the two light-emitting devices emitting the light of the same color separately correspond to the two sub-color resists transmitting the light of the different central wavelengths. Thus, according to the requirement of the first-band color pixel in the display panel for transmitting the light of the different central wavelengths, the light-emitting devices 110 corresponding to the sub-color resists transmitting the light of the central wavelengths may be controlled to emit the light, that is, different working modes are switched so that the different display requirements are satisfied and the application scenarios of the display plane are improved.

Optionally, based on the preceding embodiment, with continued reference to FIG. 2, light-emitting devices 110 in the same first-band color pixel 10 include a first light-emitting device 111 and a second light-emitting device 112, and the first-band light emission color resist 20 includes a first-subband light emission color resist 211 and a second-subband light emission color resist 212; and along the direction from the first-band light emission color resist 20 to the light-emitting devices 110, the first-subband light emission color resist 211 overlaps at least the first light-emitting device 111, and the second-subband light emission color resist 212 overlaps at least the second light-emitting device 112. The first-band color is a color corresponding to light whose band is in the range of 380 nm to 500 nm, and the central wavelength of light transmitted by the first-subband light emission color resist 211 is shorter than the central wavelength of light transmitted by the second-subband light emission color resist 212, or the maximum wavelength of light allowed to be transmitted by the first-subband light emission color resist 211 is shorter than the maximum wavelength of light allowed to be transmitted by the second-subband light emission color resist 212.

Specifically, as shown in FIG. 2, the light-emitting devices 110 in the same first-band color pixel 10 include the first light-emitting device 111 and the second light-emitting device 112, and the first light-emitting device 111 and the second light-emitting device 112 emit the light of the same color, where the first-band color may be the color corresponding to the light whose band is in the range of 380 nm to 500 nm, that is, the emitted colors of the first light-emitting device 111 and the second light-emitting device 112 in the same first-band color pixel 10 are each the first-band color; and the first-band light emission color resist 20 is further disposed on the light emission side of the first light-emitting device 111 and the light emission side of the second light-emitting device 112 and includes the first-subband light emission color resist 211 and the second-subband light emission color resist 212, and the first-subband light emission color resist 211 and the second-subband light emission color resist 212 are configured to correspond to the first light-emitting device 111 and the second light-emitting device 112, respectively, that is, along the direction from the first-band light emission color resist 20 to the light-emitting devices 110, the first-subband light emission color resist 211 overlaps at least the first light-emitting device 111, the second-subband light emission color resist 212 overlaps at least the second light-emitting device 112, and the light of the first light-emitting device 111 and the light of the second light-emitting device 112 are filtered by the first-subband light emission color resist 211 and the second-subband light emission color resist 212, respectively. The central wavelength of the light transmitted by the first-subband light emission color resist 211 is shorter than the central wavelength of the light transmitted by the second-subband light emission color resist 212, that is to say, the first-subband light emission color resist 211 can transmit the light having a relatively short central wavelength in color light of the first-band color emitted by the first light-emitting device 111, and the second-subband light emission color resist 212 can transmit the light having a relatively long central wavelength in the color light of the first-band color emitted by the second light-emitting device 112. Therefore, according to the requirement for the central wavelength of the first-band color, the first light-emitting device 111 or the second light-emitting device 112 may be controlled, in the different working modes, to emit the light so that the different display requirements are satisfied and the application scenarios of the display plane are improved.

It is to be noted that during an actual measurement, since the central wavelength is relatively flat and is not easily determined and compared, the first-subband light emission color resist 211 and the second-subband light emission color resist 212 may be configured according to the maximum wavelength of the light allowed to be transmitted, that is, the maximum wavelength of the light allowed to be transmitted by the first-subband light emission color resist 211 is shorter than the maximum wavelength of the light allowed to be transmitted by the second-subband light emission color resist 212, so that the same effect can be achieved.

It is to be further noted that the specific color of the first-band color is not limited in the embodiments of the present disclosure as long as the color corresponds to the light whose band is in the range of 380 nm to 500 nm. In addition, for a clearer description of the solution of the present disclosure, the description is performed below using an example in which the first-band color is blue.

Optionally, with continued reference to FIG. 2, in a first working state, the first light-emitting device 111 in the first-band color pixel 10 emits the light; and in a second working state, the second light-emitting device 112 in the first-band color pixel 10 emits the light.

Specifically, the ambient light intensity in the first working state is greater than the ambient light intensity in the second working state. For example, the first working state may be the state in which the display panel works in the daytime, and the second working state may be the state in which the display panel works in the nighttime. In the first working state, only the first light-emitting device 111 in the first-band color pixel 10 may be configured to emit the light so that the first-subband light emission color resist 211 at least partially overlapping the first light-emitting device 111 filters the light to transmit the light having the relatively short central wavelength in the color light of the first-band color emitted by the first light-emitting device 111, that is, high-frequency blue light in blue light emitted by the first light-emitting device 111 is transmitted, thereby ensuring the display color gamut of the display panel and improving the display effect of the display panel. However, in the second working state, only the second light-emitting device 112 in the first-band color pixel 10 may be configured to emit the light so that the second-subband light emission color resist 212 at least partially overlapping the second light-emitting device 112 filters the light to transmit the light having the relatively long central wavelength in the color light of the first-band color emitted by the second light-emitting device 112, that is, low-frequency blue light in blue light emitted by the second light-emitting device 112 is transmitted. High-frequency blue light is filtered by the second-subband light emission color resist 212, thereby preventing the high-frequency blue light from stimulating human eyes and influencing the sleep of a user. Thus, the different working modes can be switched according to different application scenarios, thereby improving user experience.

Optionally, the central wavelength of the light transmitted by the first-subband light emission color resist 211 is less than 460 nm, and the central wavelength of the light transmitted by the second-subband light emission color resist 212 is greater than 460 nm.

Specifically, the high-frequency blue light may be blue light whose central wavelength is about 450 nm, and the low-frequency blue light may be blue light whose central wavelength is greater than 460 nm, where the central wavelength of the high-frequency blue light is shorter than the central wavelength of the low-frequency blue light. Further, the central wavelength of the light transmitted by the first-subband light emission color resist 211 is set to be less than 460 nm so that the first-subband light emission color resist 211 transmits the high-frequency blue light in the blue light emitted by the first light-emitting device 111 so that it can be ensured that the display color gamut of the display panel and the display effect of the display panel is improved, and the central wavelength of the light transmitted by the second-subband light emission color resist 212 is set to be greater than 460 nm so that the second-subband light emission color resist 212 transmits the low-frequency blue light in the blue light emitted by the second light-emitting device 112, thereby preventing the high-frequency blue light from stimulating the human eyes.

In other embodiments, the central wavelength of the light transmitted by the first-subband light emission color resist 211 is between 440 nm and 460 nm, and the central wavelength of the light transmitted by the second-subband light emission color resist 212 is between 480 nm and 500 nm.

Preferably, the central wavelength of the light transmitted by the first-subband light emission color resist 211 may be between 440 nm and 460 nm, which can further ensure that the first-subband light emission color resist 211 transmits the high-frequency blue light in the blue light emitted by the first light-emitting device 111 and ensure the color gamut of the display panel, and the central wavelength of the light transmitted by the second-subband light emission color resist 212 is between 480 nm and 500 nm, which can further ensure that the second-subband light emission color resist 212 transmits the low-frequency blue light in the blue light emitted by the second light-emitting device 112, thereby preventing the high-frequency blue light from stimulating the human eyes.

Optionally, FIG. 3 is another sectional view along AA′ in FIG. 1, and referring to FIG. 3, the display panel further includes the array substrate 100, where a projection of the first-subband light emission color resist 211 on the plane where the array substrate 100 is located covers the first light-emitting device 111, and a projection of the second-subband light emission color resist 212 on the plane where the array substrate 100 is located covers the second light-emitting device 112; and a projection area of the first light-emitting device 111 on the plane where the array substrate 100 is located is different from a projection area of the second light-emitting device 112 on the plane where the array substrate 100 is located.

Specifically, as shown in FIG. 3, along the direction from the first-band light emission color resist 20 to the light-emitting devices 110, the first-subband light emission color resist 211 completely covers the first light-emitting device 111, and the second-subband light emission color resist 212 completely covers the second light-emitting device 112, that is to say, the projection of the first-subband light emission color resist 211 on the plane where the array substrate 100 is located covers the first light-emitting device 111, and the projection of the second-subband light emission color resist 212 on the plane where the array substrate 100 is located covers the second light-emitting device 112, so that it is ensured that all the blue light emitted by the first light-emitting device 111 can be filtered by the first-subband light emission color resist 211, that is, the high-frequency blue light is transmitted, and a blue display is finally performed, and all the blue light emitted by the second light-emitting device 112 can be filtered by the second-subband light emission color resist 212, that is, the low-frequency blue light is transmitted, and a blue-green display is finally performed. Thus, the projection of the first-subband light emission color resist 211 on the plane where the array substrate 100 is located is configured to cover the first light-emitting device 111, and the projection of the second-subband light emission color resist 212 on the plane where the array substrate 100 is located is configured to cover the second light-emitting device 112, thereby avoiding the problem of a non-uniform display caused by the failure of the first-band light emission color resist 20 to completely cover the light-emitting devices 110.

It is to be noted that the projection area of the first light-emitting device 111 on the plane where the array substrate 100 is located is different from the projection area of the second light-emitting device 112 on the plane where the array substrate 100 is located. According to requirements, those skilled in the art may set the projection area of the first light-emitting device 111 on the plane where the array substrate 100 is located to be larger than the projection area of the second light-emitting device 112 on the plane where the array substrate 100 is located or may set the projection area of the first light-emitting device 111 on the plane where the array substrate 100 is located to be smaller than the projection area of the second light-emitting device 112 on the plane where the array substrate 100 is located, which is not limited in the present disclosure. The two cases are separately described below in conjunction with embodiments.

Optionally, with continued reference to FIG. 3, the projection area of the first light-emitting device 111 on the plane where the array substrate 100 is located is smaller than the projection area of the second light-emitting device 112 on the plane where the array substrate 100 is located.

Specifically, since the central wavelength of the light transmitted by the second-subband light emission color resist 212 is longer than the central wavelength of the light transmitted by the first-subband light emission color resist 211 and the second-subband light emission color resist 212 is configured to correspond to the second light-emitting device 112, the second-subband light emission color resist 212 can transmit the light having the relatively long central wavelength in the blue light emitted by the second light-emitting device 112. In other words, the second-subband light emission color resist 212 transmits the low-frequency blue light in the blue light emitted by the second light-emitting device 112 and blocks the high-frequency blue light in the blue light emitted by the second light-emitting device 112, which results in relatively low brightness (since the wavelength is relatively long, the color is slightly greenish) of the blue light finally emitted by the second light-emitting device 112. Therefore, the projection area of the first light-emitting device 111 on the plane where the array substrate 100 is located may be set to be smaller than the projection area of the second light-emitting device 112 on the plane where the array substrate 100 is located. That is, the projection area of the second light-emitting device 112 on the plane where the array substrate 100 is located is increased so that the brightness of the blue light in the blue-green light emitted by the second light-emitting device 112 is similar to the brightness of the blue light emitted by the first light-emitting device 111 or it is ensured that the brightness of the blue-green light emitted by the second light-emitting device 112 is similar to the brightness of color light emitted by other sub-pixels 01, thereby ensuring the display uniformity of the display panel.

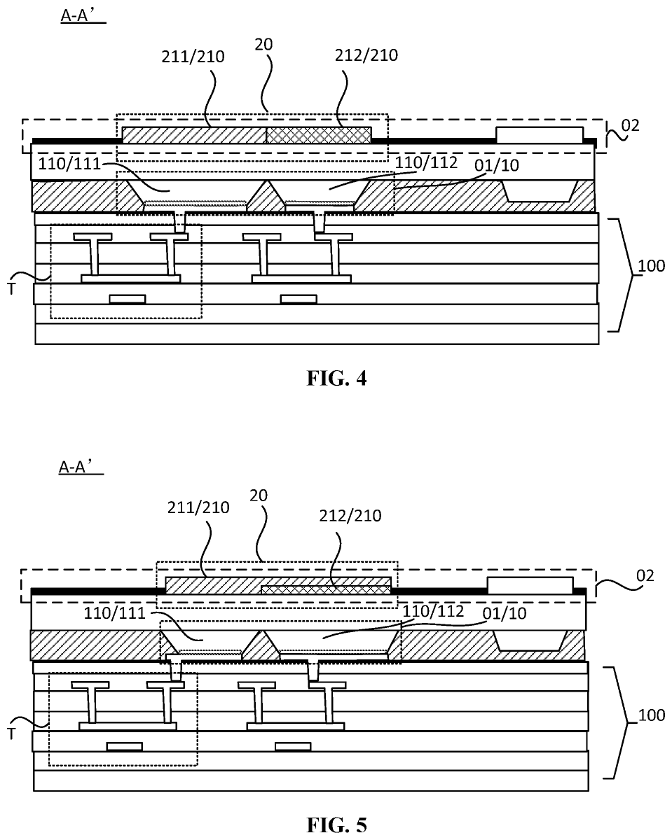

In another embodiment, FIG. 4 is another sectional view along AA′ in FIG. 1, and referring to FIG. 4, the projection area of the first light-emitting device 111 on the plane where the array substrate 100 is located is larger than the projection area of the second light-emitting device 112 on the plane where the array substrate 100 is located.

Specifically, the size relationship between the projection area of the first light-emitting device 111 on the plane where the array substrate 100 is located and the projection area of the second light-emitting device 112 on the plane where the array substrate 100 is located may be set according to requirements for viewing angles in different working states. For example, the first working state may be the state in which the display panel works in the daytime, and the second working state may be the state in which the display panel works in the nighttime. In the first working state, the viewing angle of the display panel is required to tend to be a large viewing angle. Therefore, the projection area of the first light-emitting device 111 on the plane where array substrate 100 is located may be increased so that a viewing angle supported by the first light-emitting device 111 for a display is caused to be larger. In other words, the display effect of the large viewing angle of the display panel is further improved in the first working state. However, in the second working state, the viewing angle of the display panel is required to tend to be a small viewing angle. Therefore, the projection area of the second light-emitting device 112 on the plane where array substrate 100 is located may be set to be relatively small, and the display effect of the display panel is improved in conjunction with a static use environment.

Optionally, the first light-emitting device 111 and the second light-emitting device 112 share the same evaporation opening. Specifically, when the first light-emitting device 111 and the second light-emitting device 112 are formed through evaporation, the same evaporation opening may be used. Thus, the spacing between the first light-emitting device 111 and the second light-emitting device 112 can be reduced so that a pixel size can be compressed and a process can be simplified.

Optionally, with continued reference to FIG. 2, the first light-emitting device 111 includes a first electrode 1110, a first light-emitting layer 1111, and a second electrode 1112 which are stacked, and the second light-emitting device 112 includes a third electrode 1120, a second light-emitting layer 1121, and a fourth electrode 1122 which are stacked; where the first electrode 1110 and the third electrode 1120 are formed synchronously with the same process, the first light-emitting layer 1111 and the second light-emitting layer 1121 are formed synchronously with the same process, and the second electrode 1112 and the fourth electrode 1122 are formed synchronously with the same process.

Specifically, the first electrode 1110 and the third electrode 1120 may be anodes, and the second electrode 1112 and the fourth electrode 1122 may be cathodes. After voltages are applied to the anodes and the cathodes, the first light-emitting device 111 and the second light-emitting device 112 emit the light. During manufacture, the first electrode 1110 and the third electrode 1120 may be manufactured in the same manufacturing process with the same mask, and masks do not need to be separately manufactured for the first electrode 1110 and the third electrode 1120, thereby saving costs, reducing the number of manufacturing steps, and improving production efficiency. The first light-emitting layer 1111 and the second light-emitting layer 1121 may be manufactured in the same manufacturing process with the same mask, and masks do not need to be separately manufactured for the first light-emitting layer 1111 and the second light-emitting layer 1121, thereby saving the costs, reducing the number of manufacturing steps, and improving the production efficiency. The second electrode 1112 and the fourth electrode 1122 may be manufactured in the same manufacturing process with the same mask, and masks do not need to be separately manufactured for the second electrode 1112 and the fourth electrode 1122, thereby saving the costs, reducing the number of manufacturing steps, and improving the production efficiency.

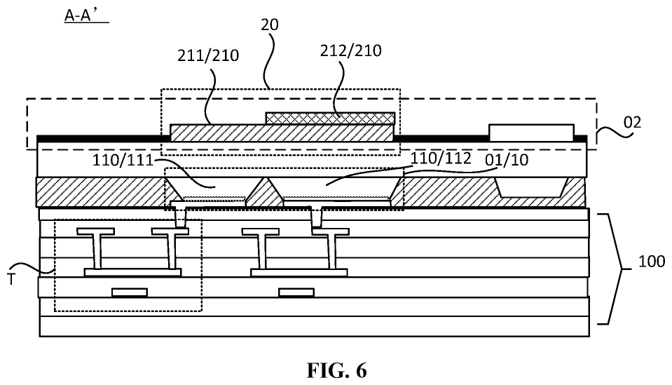

Optionally, FIG. 5 is another sectional view along AA′ in FIG. 1, and referring to FIG. 5, along the direction from the first-band light emission color resist 20 to the light-emitting devices 110, the first-subband light emission color resist 211 further overlaps the second light-emitting device 112.

Specifically, as shown in FIG. 5, along the direction from the first-band light emission color resist 20 to the light-emitting devices 110, the first-subband light emission color resist 211 overlaps the second light-emitting device 112, and the first-subband light emission color resist 211 also overlaps the second-subband light emission color resist 212, that is, along the direction from the first-subband light emission color resist 211 to the light-emitting devices 110, the first-subband light emission color resist 211 includes a portion overlapping the first light-emitting device 111 and a portion overlapping the second light-emitting device 112. The blue light emitted by the first light-emitting device 111 is filtered by the first-subband light emission color resist 211, and the blue light emitted by the second light-emitting device 112 is filtered by the first-subband light emission color resist 211 and the second-subband light emission color resist 212 so that the light emitted by the first light-emitting device 111 is displayed as the blue light, and light emitted by the second light-emitting device 112 is displayed as the blue-green light. Thus, according to the different working modes of the display panel, the first light-emitting device 111 or the second light-emitting device 112 is controlled to emit the light so that the display requirements of the different working modes of the display panel are satisfied and the application scenarios of the display panel are improved.

It is to be understood that the first-subband light emission color resist 211 includes the portion overlapping the first light-emitting device 111 and the portion overlapping the second light-emitting device 112, and the two portions are a continuous structure or the first-subband light emission color resist 211 is integrally formed.

It is to be noted that relative positions of the first-subband light emission color resist 211 and the second-subband light emission color resist 212 are not limited in the embodiments of the present disclosure as long as the first-subband light emission color resist 211 overlaps the second light-emitting device 112 along the direction from the first-band light emission color resist 20 to the light-emitting devices 110. Two positional relationships of the first-subband light emission color resist 211 and the second-subband light emission color resist 212 are separately described below in conjunction with embodiments.

In an embodiment, with continued reference to FIG. 5, the second-subband light emission color resist 212 is disposed on a side of the first-subband light emission color resist 211 facing the second light-emitting device 112, and the thickness of a first-subband light emission color resist 211 overlapping the second light-emitting device 112 is less than the thickness of a first-subband light emission color resist 211 overlapping the first light-emitting device 111.

Specifically, as shown in FIG. 5, along the direction from the first-band light emission color resist 20 to the light-emitting devices 110, the second-subband light emission color resist 212 is disposed on the side of the first-subband light emission color resist 211 facing the second light-emitting device 112, that is, the blue light emitted by the second light-emitting device 112 is filtered by the second-subband light emission color resist 212 and then filtered by the first-subband light emission color resist 211. The central wavelength of the light transmitted by the second-subband light emission color resist 212 is longer than the central wavelength of the light transmitted by the first-subband light emission color resist 211. For example, the central wavelength of the light transmitted by the first-subband light emission color resist 211 may be less than 460 nm, that is, more high-frequency blue light is transmitted and less low-frequency blue light is transmitted, and the central wavelength of the light transmitted by the second-subband light emission color resist 212 may be greater than 460 nm, that is, more low-frequency blue light is transmitted and less high-frequency blue light is transmitted. Thus, after passing through the second-subband light emission color resist 212 and the first-subband light emission color resist 211, the low-frequency blue light finally transmitted is in a larger portion than the proportion of the high-frequency blue light, the light emitted by the second light-emitting device 112 is finally displayed as the blue-green light. In addition, since the first-subband light emission color resist 211 is stacked on the second-subband light emission color resist 212 corresponding to the second light-emitting device 112, the first-subband light emission color resist 211 can assist in filtering light of unnecessary colors, thereby reducing the light filtering burden of the second-subband light emission color resist 212.

In addition, along the direction from the first-band light emission color resist 20 to the light-emitting devices 110, the thickness of the first-subband light emission color resist 211 overlapping the second light-emitting device 112 may be set to be less than the thickness of the first-subband light emission color resist 211 overlapping the first light-emitting device 111. For example, along the direction from the first-band light emission color resist 20 to the light-emitting devices 110, the thickness of the first-subband light emission color resist 211 overlapping the second light-emitting device 112 and the second-subband light emission color resist 212 overlapping the second light-emitting device 112 may be equal to the thickness of the first-subband light emission color resist 211 overlapping the first light-emitting device 111. Thus, in the portion corresponding to the second light-emitting device 112, the thickness of the first-subband light emission color resist 211 in this position may be reduced because of the presence of the second-subband light emission color resist 212, which can increase the transmittance of this region and compensate for brightness loss caused by the second-subband light emission color resist 212. Further, in the embodiment, since the projection area of the second light-emitting device 112 on the plane where the array substrate 100 is located does not need to be increased to compensate for the final display brightness of the second light-emitting device 112, the projection area of the second light-emitting device 112 on the plane where the array substrate 100 is located can be indirectly reduced, and the overall aperture ratio can be improved. In addition, the first-subband light emission color resist 211 covers the second-subband light emission color resist 212 along the direction from the first-band light emission color resist 20 to the light-emitting devices 110. Therefore, in a manufacturing step, compared with the solution that the first-subband light emission color resist 211 and the second-subband light emission color resist 212 are configured to correspond to the first light-emitting device 111 and the second light-emitting device 112, the stray light problem caused by the overlap of the edge of the first-subband light emission color resist 211 and the edge of the second-subband light emission color resist 212 can be avoided.

Optionally, the second-subband light emission color resist 212 includes indium tin oxide or cuprous oxide. Specifically, the second-subband light emission color resist 212 may be prepared by a physical vapor deposition process, and the material of the second-subband light emission color resist 212 may be a narrow band-gap inorganic material such as the indium tin oxide or the cuprous oxide. Indium tin oxide is a substitutional solid solution, which is in the shape of a transparent tan film or a yellowish-gray block. The indium tin oxide is mainly used for manufacturing liquid crystal displays, flat-panel displays, plasma displays, touchscreens, electronic papers, organic light-emitting diodes, antistatic coating films, EMI-shielding transparent conducting coatings, various optical coating films, and the like. The main characteristic of the indium tin oxide is a combination of electrical conductivity and optical transparency, thereby facilitating the increase of the transmittance of the second-subband light emission color resist 212.

In another embodiment, FIG. 6 is another sectional view along AA′ in FIG. 1, and referring to FIG. 6, the second-subband light emission color resist 212 is disposed on a side of the first-subband light emission color resist 211 facing away from the second light-emitting device 112, the second-subband light emission color resist 212 and the first-subband light emission color resist 211 are made of the same material, and the second-subband light emission color resist 212 is doped with a material absorbing light whose central wavelength is less than 460 nm.

Specifically, as shown in FIG. 6, along the direction from the first-band light emission color resist 20 to the light-emitting devices 110, the second-subband light emission color resist 212 is disposed on the side of the first-subband light emission color resist 211 facing away from the second light-emitting device 112, that is, the blue light emitted by the second light-emitting device 112 is filtered by the first-subband light emission color resist 211 and then filtered by the second-subband light emission color resist 212. The second-subband light emission color resist 212 and the first-subband light emission color resist 211 are made of the same material, and the second-subband light emission color resist 212 is doped with the material absorbing light whose central wavelength is less than 460 nm so that the second-subband light emission color resist 212 absorbs the light whose central wavelength is less than 460 nm, that is, the second-subband light emission color resist 212 absorbs the high-frequency blue light so that more low-frequency blue light is transmitted. The first-subband light emission color resist 211 may be doped with a material absorbing light whose central wavelength is greater than 460 nm, that is, the first-subband light emission color resist 211 transmits more high-frequency blue light and less low-frequency blue light. Thus, after the light is filtered by the first-subband light emission color resist 211 and the second-subband light emission color resist 212, the second light-emitting device 112 finally performs the blue-green display. In addition, the second-subband light emission color resist 212 is disposed on the side of the first-subband light emission color resist 211 facing away from the second light-emitting device 112. That is, along the direction from the first-band light emission color resist 20 to the light-emitting devices 110, the second-subband light emission color resist 212 is disposed in a position overlapping the second light-emitting device 112 to cover the first-subband light emission color resist 211. Thus, a problem caused by difficulty in controlling edges of light emission color resists with a process in the manufacturing steps can be avoided.

Optionally, with continued reference to FIGS. 1 and 2, the shape of the light emission surface of the second-subband light emission color resist 212 is the same as the shape of a side surface of the second light-emitting device 112 facing the second-subband light emission color resist 212. Specifically, since the first-subband light emission color resist 211 further overlaps the second light-emitting device 112 along the direction from the first-band light emission color resist 20 to the light-emitting devices 110, the shape of the light emission surface of the second-subband light emission color resist 212 is configured to be the same as the shape of the side surface of the second light-emitting device 112 facing the second-subband light emission color resist 212 so that it is ensured that the light emitted by the second light-emitting device 112 is filtered by the first-subband light emission color resist 211 and can also be filtered by the second-subband light emission color resist 212 whose shape is the same as the shape of the side surface of the second light-emitting device 112 facing the second-subband light emission color resist 212. Thus, the problem is avoided that the shape of the light emission surface of the second-subband light emission color resist 212 is different from the shape of the side surface of the second light-emitting device 112 facing the second-subband light emission color resist 212, resulting in the non-uniform display caused by light leakage.

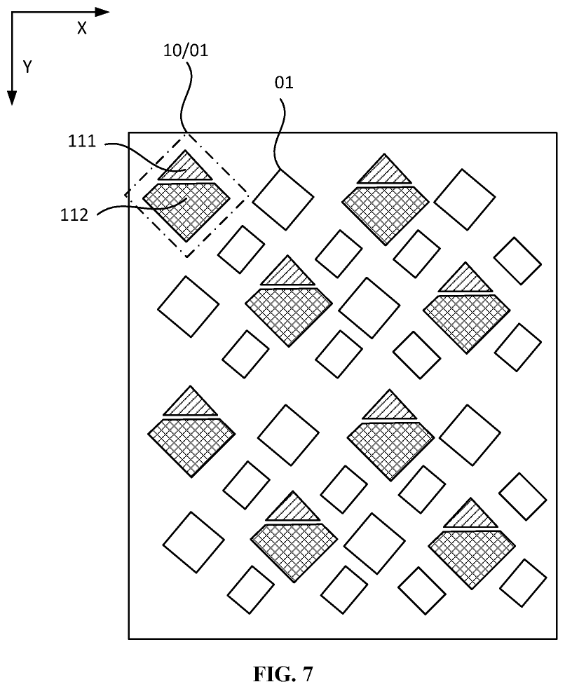

Based on the preceding embodiments, FIG. 7 is a structural diagram of another display panel according to an embodiment of the present disclosure, and referring to FIG. 7, multiple first-band color pixels 10 are arranged in an array, and first light-emitting devices 111 and second light-emitting devices 112 are arranged along the column direction of the array.

Specifically, as shown in FIG. 7, the display panel includes the sub-pixels 01 including the first-band color pixels 10, the multiple first-band color pixels 10 are arranged in the array, and the one first-band color pixel 10 includes at least the first light-emitting device 111 and the second light-emitting device 112 which emit the light of the same color, where the first light-emitting devices 111 and the second light-emitting devices 112 are arranged along the column direction of the array. Along the direction from the first-band light emission color resist 20 to the light-emitting devices 110, the first-subband light emission color resist 211 overlaps at least the first light-emitting device 111, the second-subband light emission color resist 212 overlaps at least the second light-emitting device 112, and the central wavelength of the light transmitted by the first-subband light emission color resist 211 is shorter than the central wavelength of the light transmitted by the second-subband light emission color resist 212. That is to say, the blue light emitted by the first light-emitting device 111 and the blue light emitted by the second light-emitting device 112 are filtered by the first-subband light emission color resist 211 and the second-subband light emission color resist 212 respectively and finally displayed as the blue light and the blue-green light. Further, the first light-emitting devices 111 by which the blue light is finally displayed and the second light-emitting devices 112 by which the blue-green light is finally displayed are configured to be arranged in the column direction Y of the array so that the emitted colors of the first light-emitting devices 111 and the emitted colors of the second light-emitting devices 112 from different viewing angles along the row direction X of the array (the row direction X of the array may be perpendicular to the column direction Y) do not interfere with each other, thereby avoiding the problem of a color cast from a particular angle.

Optionally, with continued reference to FIG. 7, the first light-emitting devices 111 and the second light-emitting devices 112 are alternately arranged along the column direction Y of the array. Specifically, as shown in FIG. 7, the arrangement sequences of the first light-emitting devices 111 and the second light-emitting devices 112 of the first-band color pixels 10 in the display panel may be the same, that is, the first light-emitting devices 111 and the second light-emitting devices 112 are alternately arranged along the column direction Y of the array, so that the problem of a color cast from a large viewing angle of a particular direction can be alleviated.

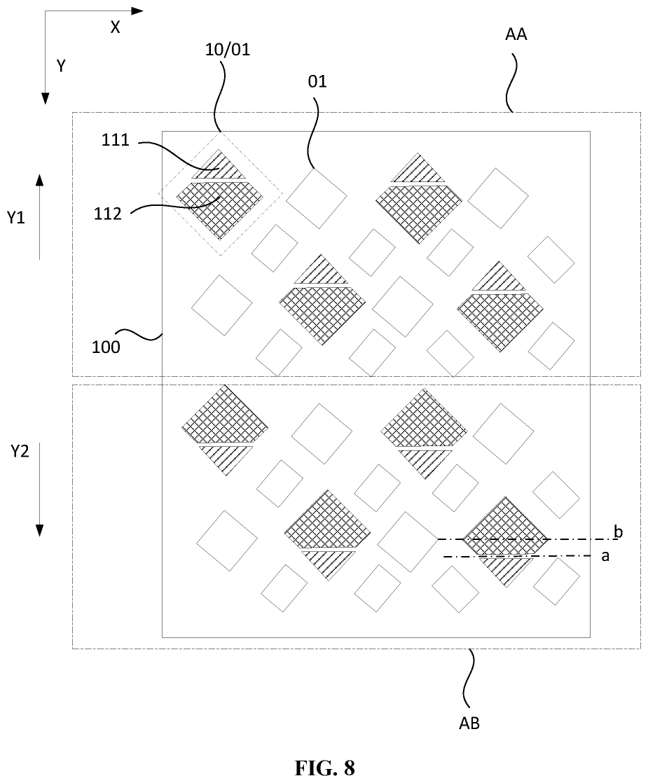

Optionally, in other embodiments, FIG. 8 is a structural diagram of another display panel according to an embodiment of the present disclosure, and referring to FIG. 8, at least two of the first light-emitting devices 111 and/or at least two of the second light-emitting devices 112 are adjacently disposed along the column direction Y of the array. Specifically, as shown in FIG. 8, the arrangement sequences of the first light-emitting devices 111 and the second light-emitting devices 112 in different first-band color pixels 10 may be different along the column direction Y of the array. For example, the arrangement directions of first light-emitting devices 111 and second light-emitting devices 112 in the same row of first-band color pixels 10 are the same along the row direction X of the array while the arrangement sequences of first light-emitting devices 111 and second light-emitting devices 112 in two adjacent first-band color pixels 10 are opposite along the column direction Y of the array. That is, the at least two first light-emitting devices 111 and/or the at least two second light-emitting devices 112 are adjacently disposed so that color casts in various directions can be distributed more uniformly.

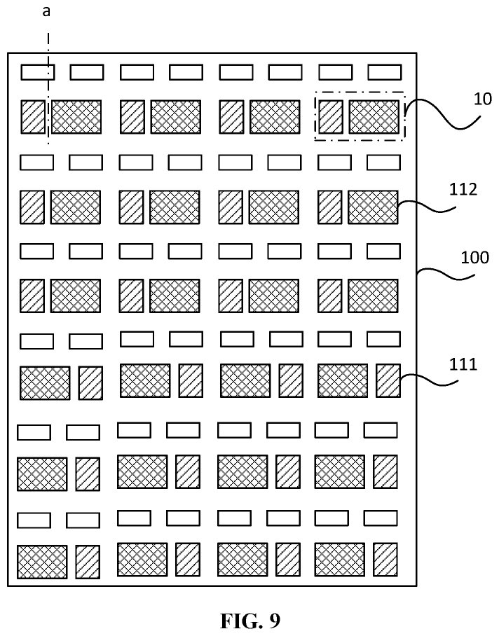

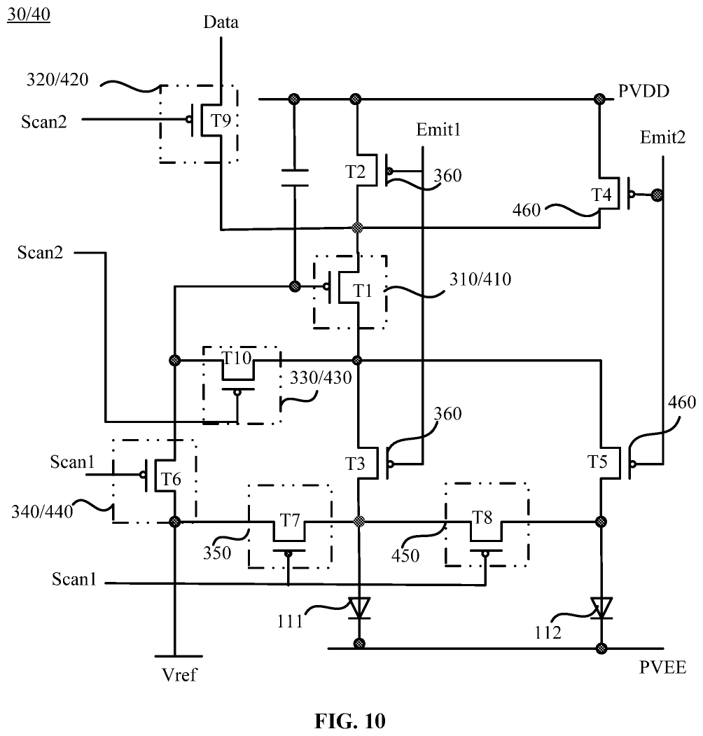

Optionally, FIG. 9 is a structural diagram of another display panel according to an embodiment of the present disclosure, and referring to FIG. 9, the display panel further includes the array substrate 100, where in the same first-band color pixel 10, a projection contour of the first light-emitting device 111 on the plane where the array substrate 100 is located and a projection contour of the second light-emitting device 112 on the plane where the array substrate 100 is located constitute a rectangle, and the boundary a between the first light-emitting device 111 and the second light-emitting device 112 is parallel to two sides of the rectangle.

Specifically, as shown in FIG. 9, a projection shape of the first light-emitting device 111 on the plane where the array substrate 100 is located may be a first rectangle, a projection shape of the second light-emitting device 112 on the plane where the array substrate 100 is located may be a second rectangle, the length of the first rectangle may be equal to the width of the second rectangle, and a long side of the first rectangle is adjacent to a wide side of the second rectangle so that the projection contour of the first light-emitting device 111 on the plane where the array substrate 100 is located and the projection contour of the second light-emitting device 112 on the plane where the array substrate 100 is located constitute the rectangle; and the boundary a exists between the first light-emitting device 111 and the second light-emitting device 112 in the same first-band color pixel 10 and is parallel to two wide sides of the rectangle constituted by the first light-emitting device 111 and the second light-emitting device 112. Thus, the projection contour of the first light-emitting device 111 on the plane where the array substrate 100 is located and the projection contour of the second light-emitting device 112 on the plane where the array substrate 100 is located are configured to constitute the rectangle so that the first-band color pixels 10 can be arranged in a simple manner.

Optionally, based on the preceding embodiments, with continued reference to FIG. 8, the display panel further includes the array substrate 100, where in the same first-band color pixel 10, the projection contour of the first light-emitting device 111 on the plane where the array substrate 100 is located and the projection contour of the second light-emitting device 112 on the plane where the array substrate 100 is located constitute a rectangle or a rhombus, and the boundary a between the first light-emitting device 111 and the second light-emitting device 112 is parallel to a first diagonal b of the rectangle or a first diagonal b of the rhombus.

Specifically, as shown in FIG. 8, the projection shape of the first light-emitting device 111 on the plane where the array substrate 100 is located may be a triangle, and the projection shape of the second light-emitting device 112 on the plane where the array substrate 100 is located may be a rectangle or a rhombus with a missing angle so that the projection contour of the first light-emitting device 111 on the plane where the array substrate 100 is located and the projection contour of the second light-emitting device 112 on the plane where the array substrate 100 is located constitute the rectangle or the rhombus. The rectangle may be a rectangle rotated by a certain angle or may be understood as a rhombus having an internal angle of 90°, and the boundary a exists between the first light-emitting device 111 and the second light-emitting device 112 in the same first-band color pixel 10 and is parallel to the first diagonal b of the rectangle or the rhombus constituted by the first light-emitting device 111 and the second light-emitting device 112, that is, the boundary a is parallel to the row direction X of the array. Thus, the projection contour of the first light-emitting device 111 on the plane where the array substrate 100 is located and the projection contour of the second light-emitting device 112 on the plane where the array substrate 100 is located are configured to constitute the rectangle or the rhombus so that the first-band color pixels 10 can be arranged in a simple manner.

Based on the preceding embodiments, with continued reference to FIG. 8, the multiple first-band color pixels 10 are arranged in the array, and the first light-emitting devices 111 and the second light-emitting devices 112 are arranged along the column direction Y of the array; and the display panel includes a first region AA and a second region AB arranged in the column direction Y of the array, a boundary a in the first region AA is disposed on a side of a respective first diagonal b facing a first sub-direction Y1, and a boundary a in the second region AB is disposed on a side of a respective first diagonal b facing a second sub-direction Y2, where the first sub-direction Y1 and the second sub-direction Y2 are opposite to each other and are each parallel to the column direction of the array.

Specifically, as shown in FIG. 8, the display panel includes the sub-pixels 01 including the first-band color pixels 10, the multiple first-band color pixels 10 are arranged in the array, and the one first-band color pixel 10 includes at least the first light-emitting device 111 and the second light-emitting device 112 which emit the light of the same color, where the first light-emitting devices 111 and the second light-emitting devices 112 are arranged along the column direction Y of the array. Further, the display panel includes the first region AA and the second region AB arranged in the column direction Y of the array. The first region AA includes multiple rows of first-band color pixels 10, and the arrangement sequences of first light-emitting devices 111 and second light-emitting devices 112 in the first region AA are the same, that is, the boundary a in the first region AA is disposed on the side of the first diagonal b facing the first sub-direction Y1. That is to say, the first light-emitting device 111 is disposed on the upper side of the boundary a, and the second light-emitting device 112 is disposed on the lower side of the boundary a. The second region AB includes multiple rows of first-band color pixels 10, and the arrangement sequences of first light-emitting devices 111 and second light-emitting devices 112 in the second region AB are the same and opposite to the arrangement sequences of the first light-emitting devices 111 and the second light-emitting devices 112 in the first region AA, that is, the boundary a in the second region AB is disposed on the side of the first diagonal b facing the first sub-direction Y2. That is to say, the first light-emitting device 111 is disposed on the lower side of the boundary a, and the second light-emitting device 112 is disposed on the upper side of the boundary a in the second region AB. The at least two first light-emitting devices 111 and/or the at least two second light-emitting devices 112 are adjacently disposed so that the color casts in the various directions can be distributed more uniformly. In addition, when the user watches the display panel, the human eyes typically face the central region of the display panel directly. Therefore, the directions of the large viewing angles of the two edge regions on the upper and lower sides of the display panel are exactly opposite. Therefore, the arrangement sequences of the first light-emitting devices 111 and the second light-emitting devices 112 in the first region AA are configured to be symmetrical (opposite) to the arrangement sequences of the first light-emitting devices 111 and the second light-emitting devices 112 in the second region AB with respect to the central region of the display panel so that the problem can be alleviated that the directions of the large viewing angles of different regions are opposite, thereby improving the display effects of the large viewing angles.

Optionally, the first light-emitting device 111 includes any one of an organic light-emitting diode (OLED), a micro light-emitting diode (micro LED), or a mini light-emitting diode (mini LED), and the second light-emitting device 112 includes any one of the OLED, the micro LED, or the mini LED. The OLED is a device which uses a multi-layer organic film structure to generate electroluminescence. The OLED is easy to manufacture, requires only a low drive voltage, and is characterized by low power consumption, fast response, a relatively wide viewing angle, and the like. The micro LED has a LED structure designed with being thinned, miniaturized, and arrayed, and a size of the micro LED is only from 1 um to 100 um so that a high resolution display can be implemented. The mini LED (the mini light-emitting diode) has advantages such as lower power consumption, faster response, higher resolution, higher contrast, and long lifetime, attracts much attention in the field of display technologies, and is commonly used in light-emitting modules in display devices. Thus, the first light-emitting device 111 and the second light-emitting device 112 are configured to each include any one of the OLED, the micro LED, or the mini LED, which is conducive to improving the display effect of the display panel.

It is to be noted that the first light-emitting device 111 and the second light-emitting device 112 may be the same light-emitting device or different light-emitting devices, which is not limited in the present disclosure.

Optionally, FIG. 10 is a circuit diagram of a pixel circuit according to an embodiment of the present disclosure, and referring to FIG. 10, the display panel further includes a first pixel circuit 30 and a second pixel circuit 40, where the first pixel circuit 30 is configured to drive the first light-emitting device 111 to emit the light, and the second pixel circuit 40 is configured to drive the second light-emitting device 112 to emit the light.

The first pixel circuit 30 includes a first drive module 310, a first data write module 320, a first threshold compensation module 330, a first initialization module 340, a second initialization module 350, and a first light emission control module 360, and the second pixel circuit 40 includes a second drive module 410, a second data write module 420, a second threshold compensation module 430, a third initialization module 440, a fourth initialization module 450, and a second light emission control module 460. The first drive module 310 also serves as the second drive module 410, the first data write module 320 also serves as the second data write module 420, the first threshold compensation module 330 also serves as the second threshold compensation module 430, and the first initialization module 340 also serves as the third initialization module 440.

Specifically, as shown in FIG. 10, the first pixel circuit 30 includes the first drive module 310, the first data write module 320, the first threshold compensation module 330, the first initialization module 340, the second initialization module 350, and the first light emission control module 360. The first data write module 320 and the threshold compensation module 330 are each disposed on the write path of a data signal and are configured to write the data signal to the input terminal of the first drive module 310 to control the working state of the first drive module 310, thereby controlling the magnitude of a drive current and the brightness of the first light-emitting device 111. The output terminal of the first initialization module 340 is electrically connected to the control terminal of the first drive module 310 and is configured to reset control terminal potential of the first drive module 310. The output terminal of the second initialization module 350 is electrically connected to the first light-emitting device 111 and is configured to reset the anode of the first light-emitting device 111, so as to avoid the influence of light emission for a previous frame on light emission for a current frame. The first light emission control module 360 is connected in series on a light emission path, that is, between a first power voltage terminal PVDD and a second power voltage terminal PVEE. The control terminals of the first light emission control modules 360 are each electrically connected to a light emission control signal output terminal Emit. A light emission control signal inputted by the light emission control signal input terminal Emit is used for controlling the working state of the first light-emitting device 111 at a light emission stage.

The second pixel circuit 40 includes the second drive module 410, the second data write module 420, the second threshold compensation module 430, the third initialization module 440, the fourth initialization module 450, and the second light emission control module 460. The modules in the second pixel circuit 40 have the same functions as the modules in the first pixel circuit 30, and the details are not repeated here. Further, the first drive module 310 also serves as the second drive module 410, the first data write module 320 also serves as the second data write module 420, the first threshold compensation module 330 also serves as the second threshold compensation module 430, and the first initialization module 340 also serves as the third initialization module 440 so that the pixel circuit can be simplified and the control manner of the circuit is simple.

Optionally, with continued reference to FIG. 10, the first drive module 310 includes a first transistor T1, the first light emission control module 360 includes a second transistor T2 and a third transistor T3, the second light emission control module 460 includes a fourth transistor T4 and a fifth transistor T5, the first initialization module 340 includes a sixth transistor T6, the second initialization module 350 includes a seventh transistor T7, the fourth initialization module 450 includes an eighth transistor T8, the first data write module 320 includes a ninth transistor T9, and the first threshold compensation module 330 includes a tenth transistor T10. The first terminal of the second transistor T2 and the first terminal of the fourth transistor T4 are each connected to the first power voltage terminal PVDD, the second terminal of the second transistor T2 and the second terminal of the fourth transistor T4 are each connected to the first terminal of the first transistor T1, the first terminal of the third transistor T3 and the first terminal of the fifth transistor T5 are each connected to the second terminal of the first transistor T1, the control terminal of the second transistor T2 and the control terminal of the third transistor T3 are each connected to a first light emission control signal terminal Emit1, the control terminal of the fourth transistor T4 and the control terminal of the fifth transistor T5 are each connected to a second light emission control terminal Emit2, the second terminal of the third transistor T3 is connected to the first electrode of the first light-emitting device 111, the second terminal of the fifth transistor T5 is connected to the first electrode of the second light-emitting device 112, the second electrode of the first light-emitting device 111 and the second electrode of the second light-emitting device 112 are each connected to the second power voltage terminal PVEE. The control terminal of the sixth transistor T6 is connected to a first scan signal line Scan1, the first terminal of the sixth transistor T6 is connected to a reference power signal terminal Vref, the second terminal of the sixth transistor T6 is connected to the control terminal of the first transistor T1, the control terminal of the tenth transistor T10 is connected to a second scan signal line Scan2, the first terminal of the tenth transistor T10 is connected to the second terminal of the first transistor T1, the second terminal of the tenth transistor T10 is connected to the control terminal of the first transistor T1, the first terminal of the ninth transistor T9 is connected to a data signal terminal Data, the second terminal of the ninth transistor T9 is connected to the first terminal of the first transistor T1, the control terminal of the ninth transistor T9 is connected to a second scan signal line Scan2, the first terminal of the seventh transistor T7 is connected to a reference voltage signal terminal Vref, the second terminal of the seventh transistor T7 is connected to the first electrode of the first light-emitting device 111, the first terminal of the eighth transistor T8 is connected to the second terminal of the seventh transistor T7, the second terminal of the eighth transistor T8 is connected to the first electrode of the second light-emitting device 112, and the control terminal of the seventh transistor T7 and the control terminal of the eighth transistor T8 are each connected to the first scan signal line Scan1. Optionally, the first terminal of the seventh transistor T7 and the first terminal of the eighth transistor T8 are each connected to the reference voltage signal terminal Vref, and the seventh transistor T7 and the eighth transistor T8 reset the first light-emitting device 111 and the second light-emitting device 112 through the reference power signal terminal Vref, respectively.

Specifically, scan signal line include the first scan signal line Scan1 and the second scan signal line Scan2, the first initialization module 340 includes the sixth transistor T6, the first drive module 310 includes the first transistor T1, the first terminal of the sixth transistor T6 is connected to the reference power signal terminal Vref, the second terminal of the sixth transistor T6 is connected to the control terminal of the first transistor T1, the control terminal of the sixth transistor T6 is connected to the first scan signal line Scan1, the first data write module 320 includes a ninth transistor T9, the control terminal of the ninth transistor T9 is electrically connected to the second scan signal line Scan2, and working stages of the first pixel circuit 30 and the second pixel circuit 40 further includes an initialization stage and a data write stage. At the initialization stage, the sixth transistor T6 is turned on, and an initialization signal is written to the control terminal of the first transistor T1. At the data write stage, the ninth transistor T9 is turned on, and the data signal is written to the control terminal of the first transistor T1. A reset and touch stage also serves as the initialization stage and/or the data write stage.

Further, the second initialization module 350 includes the seventh transistor T7, the fourth initialization module 450 includes the eighth transistor T8, the first terminal of the seventh transistor T7 is connected to the reference voltage signal terminal Vref, the second terminal of the seventh transistor T7 is connected to the first electrode of the first light-emitting device 111, the first terminal of the eighth transistor T8 is connected to the second terminal of the seventh transistor T7, the second terminal of the eighth transistor T8 is connected to the first electrode of the second light-emitting device 112, and the control terminal of the seventh transistor T7 and the control terminal of the eighth transistor T8 are each connected to the first scan signal line Scan1. Thus, the first electrode (anode) of the first light-emitting device 111 and the first electrode (anode) of the second light-emitting device 112 are reset by the seventh transistor T7 and the eighth transistor T8 respectively, thereby avoiding the influence of the light emission for the previous frame on the light emission for the current frame.

In addition, the first light emission control module 360 includes the second transistor T2 and the third transistor T3, the second transistor T2 and the third transistor T3 are disposed on the light emission path, that is, the first power voltage terminal PVDD and the second power voltage terminal PVEE, the first terminal of the second transistor T2 is connected to the first power voltage terminal PVDD, the second terminal of the second transistor T2 is connected to the first terminal of the first transistor T1, the first terminal of the third transistor T3 is connected to the second terminal of the first transistor T1, the second terminal of the third transistor T3 is connected to the first electrode of the first light-emitting device 111, and the control terminal of the second transistor T2 and the control terminal of the third transistor T3 are each connected to the first light emission control signal terminal Emit1. Thus, the working state of the first light-emitting device 111 at the light emission stage is controlled through a light emission control signal outputted by the first light emission control signal terminal Emit1.

The second light emission control module 460 includes the fourth transistor T4 and the fifth transistor T5, the fourth transistor T4 and the fifth transistor T5 are disposed on the light emission path, that is, the first power voltage terminal PVDD and the second power voltage terminal PVEE, the first terminal of the fourth transistor T4 is connected to the first power voltage terminal PVDD, the second terminal of the fourth transistor T4 is connected to the first terminal of the first transistor T1, the first terminal of the fifth transistor T5 is connected to the second terminal of the first transistor T1, the second terminal of the fifth transistor T5 is connected to the first electrode of the second light-emitting device 112, and the control terminal of the fifth transistor T5 and the control terminal of the fourth transistor T4 are each connected to the second light emission control signal terminal Emit2. Thus, the working state of the second light-emitting device 112 at the light emission stage is controlled through a light emission control signal outputted by the second light emission control signal terminal Emit2.

Thus, the first pixel circuit 30 and the second pixel circuit 40 which are separated are provided to control the first light-emitting device 111 and the second light-emitting device 112 to emit the light. In a first working mode, the first light-emitting device 111 may be controlled to emit the light by the first pixel circuit 30 so that the first-subband light emission color resist 211 at least partially overlapping the first light-emitting device 111 filters the light to transmit the light having the relatively short central wavelength in the color light of the first-band color emitted by the first light-emitting device 111, that is, the high-frequency blue light in the blue light emitted by the first light-emitting device 111 is transmitted, thereby ensuring the display color gamut of the display panel and improving the display effect of the display panel. However, in the second working state, the second light-emitting device 112 may be controlled to emit the light by the second pixel circuit 40 so that the second-subband light emission color resist 212 at least partially overlapping the second light-emitting device 112 filters the light to transmit the light having the relatively long central wavelength in the color light of the first-band color emitted by the second light-emitting device 112, that is, the low-frequency blue light in the blue light emitted by the second light-emitting device 112 is transmitted. The high-frequency blue light is filtered by the second-subband light emission color resist 212, thereby preventing the high-frequency blue light from stimulating the human eyes and influencing the sleep of the user. Thus, the different working modes can be switched according to the different application scenarios, thereby improving the user experience.

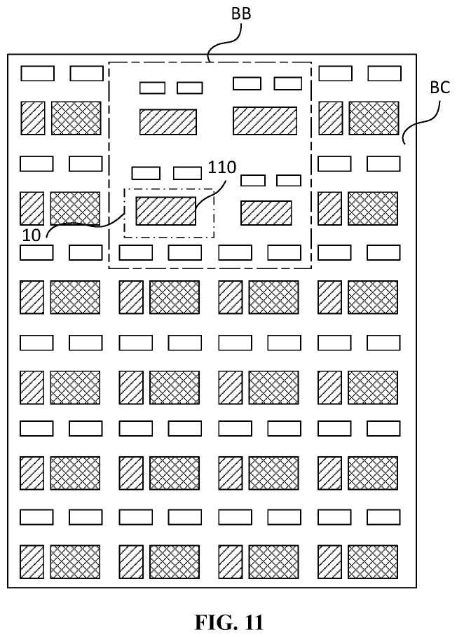

Optionally, FIG. 11 is a structural diagram of another display panel according to an embodiment of the present disclosure, and referring to FIG. 11, display regions of the display panel include a first display region BB and a second display region BC, the first display region BB includes multiple light-transmissive regions, and in the first display region BB, the first-band color pixel 10 includes one light-emitting device 110 and a light emission color resist. Specifically, as shown in FIG. 11, the display panel includes the first display region BB and the second display region BC. The transmittance of the first display region BB is greater than the transmittance of the second display region BC, that is, the first display region BB includes the multiple light-transmissive regions. Further, the first-band color pixel 10 is configured to include the one light-emitting device 110 and the light emission color resist so that the transmittance of the first display region BB is ensured.

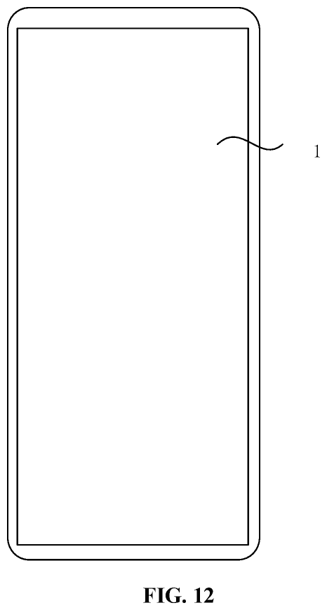

Based on the same inventive concept, an embodiment of the present disclosure further provides a display device. FIG. 12 is a structural diagram of a display device according to the embodiment of the present disclosure. As shown in FIG. 12, the display device includes the display panel 1 in the preceding embodiments. The display device includes the display panel described in any embodiment of the present disclosure. Therefore, the display device provided by the embodiment of the present disclosure has the corresponding beneficial effects of the display panel provided by the embodiments of the present disclosure, which is not repeated here. For example, the display device may be an electronic device such as a mobile phone, a computer, a smart wearable device (for example, a smart watch), or an onboard display device, which is not limited in the embodiment of the present disclosure.

It is to be noted that the preceding description is merely preferred embodiments of the present disclosure and the principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure is described in detail through the preceding embodiments, the present disclosure is not limited to the preceding embodiments and may include more equivalent embodiments without departing from the concept of the present disclosure. The scope of the present disclosure is determined by the scope of the appended claims.

What is claimed is:

1. A display panel, comprising first-band color pixels, wherein one of the first-band color pixels comprises at least two light-emitting devices emitting light of a same color; and
a color resist layer comprising first-band light emission color resists corresponding to the first-band color pixels, wherein a first-band light emission color resist of the first-band light emission color resists comprises at least two sub-color resists transmitting light of different central wavelengths.

2. The display panel according to claim 1, wherein light-emitting devices in a same first-band color pixel comprise a first light-emitting device and a second light-emitting device, and the first-band light emission color resist comprises a first-subband light emission color resist and a second-subband light emission color resist; and
along a direction from the first-band light emission color resist to the light-emitting devices, the first-subband light emission color resist overlaps at least the first light-emitting device, and the second-subband light emission color resist overlaps at least the second light-emitting device;
wherein a first-band color is a color corresponding to light whose band is in a range of 380 nm to 500 nm, and a central wavelength of light transmitted by the first-subband light emission color resist is shorter than a central wavelength of light transmitted by the second-subband light emission color resist; or
a maximum wavelength of light allowed to be transmitted by the first-subband light emission color resist is shorter than a maximum wavelength of light allowed to be transmitted by the second-subband light emission color resist.

3. The display panel according to claim 2, wherein in a first working state, the first light-emitting device in the first-band color pixel emits light; and
in a second working state, the second light-emitting device in the first-band color pixel emits light.

4. The display panel according to claim 2, wherein the central wavelength of the light transmitted by the first-subband light emission color resist is less than 460 nm, and the central wavelength of the light transmitted by the second-subband light emission color resist is greater than 460 nm.

5. The display panel according to claim 4, wherein the central wavelength of the light transmitted by the first-subband light emission color resist is between 440 nm and 460 nm, and the central wavelength of the light transmitted by the second-subband light emission color resist is between 480 nm and 500 nm.

6. The display panel according to claim 2, further comprising an array substrate, wherein a projection of the first-subband light emission color resist on a plane where the array substrate is located covers the first light-emitting device, and a projection of the second-subband light emission color resist on the plane where the array substrate is located covers the second light-emitting device; and
a projection area of the first light-emitting device on the plane where the array substrate is located is different from a projection area of the second light-emitting device on the plane where the array substrate is located.

7. The display panel according to claim 6, wherein the projection area of the first light-emitting device on the plane where the array substrate is located is smaller than the projection area of the second light-emitting device on the plane where the array substrate is located; or
the projection area of the first light-emitting device on the plane where the array substrate is located is larger than the projection area of the second light-emitting device on the plane where the array substrate is located.

8. The display panel according to claim 2, wherein the first light-emitting device and the second light-emitting device share a same evaporation opening.

9. The display panel according to claim 8, wherein the first light-emitting device comprises a first electrode, a first light-emitting layer, and a second electrode which are stacked, and the second light-emitting device comprises a third electrode, a second light-emitting layer, and a fourth electrode which are stacked;
wherein the first electrode and the third electrode are formed synchronously with a same process;
the first light-emitting layer and the second light-emitting layer are formed synchronously with a same process; and
the second electrode and the fourth electrode are formed synchronously with a same process.

10. The display panel according to claim 2, wherein along the direction from the first-band light emission color resist to the light-emitting devices, the first-subband light emission color resist further overlaps the second light-emitting device.

11. The display panel according to claim 10, wherein the second-subband light emission color resist is disposed on a side of the first-subband light emission color resist facing the second light-emitting device, and a thickness of a first-subband light emission color resist overlapping the second light-emitting device is less than a thickness of a first-subband light emission color resist overlapping the first light-emitting device; or
the second-subband light emission color resist is disposed on a side of the first-subband light emission color resist facing away from the second light-emitting device, the second-subband light emission color resist and the first-subband light emission color resist are made of a same material, and the second-subband light emission color resist is doped with a material absorbing light whose central wavelength is less than 460 nm; or
a shape of a light emission surface of the second-subband light emission color resist is the same as a shape of a side surface of the second light-emitting device facing the second-subband light emission color resist.

12. The display panel according to claim 11, wherein the second-subband light emission color resist comprises indium tin oxide or cuprous oxide.

13. The display panel according to claim 2, wherein a plurality of first-band color pixels are arranged in an array, and first light-emitting devices and second light-emitting devices are arranged along a column direction of the array.

14. The display panel according to claim 13, wherein the first light-emitting devices and the second light-emitting devices are alternately arranged along the column direction of the array; or
at least two of the first light-emitting devices and/or at least two of the second light-emitting devices are adjacently disposed along the column direction of the array.

15. The display panel according to claim 2, further comprising an array substrate, wherein in the same first-band color pixel, a projection contour of the first light-emitting device on a plane where the array substrate is located and a projection contour of the second light-emitting device on the plane where the array substrate is located constitute a rectangle, and a boundary between the first light-emitting device and the second light-emitting device is parallel to two sides of the rectangle; or
the display panel further comprises an array substrate, wherein in the same first-band color pixel, a projection contour of the first light-emitting device on a plane where the array substrate is located and a projection contour of the second light-emitting device on the plane where the array substrate is located constitute a rectangle or a rhombus, and a boundary between the first light-emitting device and the second light-emitting device is parallel to a first diagonal of the rectangle or a first diagonal of the rhombus;
wherein a plurality of first-band color pixels are arranged in an array, and first light-emitting devices and second light-emitting devices are arranged along a column direction of the array; and the display panel comprises a first region and a second region arranged in the column direction of the array, a boundary in the first region is disposed on a side of a respective first diagonal facing a first sub-direction, and a boundary in the second region is disposed on a side of a respective first diagonal facing a second sub-direction, wherein the first sub-direction and the second sub-direction are opposite to each other and are each parallel to the column direction of the array.

16. The display panel according to claim 2, wherein the first light-emitting device comprises any one of an organic light-emitting diode (OLED), a micro light-emitting diode (micro LED), or a mini light-emitting diode (mini LED), and the second light-emitting device comprises any one of the OLED, the micro LED, or the mini LED.

17. The display panel according to claim 2, further comprising a first pixel circuit and a second pixel circuit, wherein the first pixel circuit is configured to drive the first light-emitting device to emit light, and the second pixel circuit is configured to drive the second light-emitting device to emit light;
the first pixel circuit comprises a first drive module, a first data write module, a first threshold compensation module, a first initialization module, a second initialization module, and a first light emission control module, and the second pixel circuit comprises a second drive module, a second data write module, a second threshold compensation module, a third initialization module, a fourth initialization module, and a second light emission control module; and
the first drive module also serves as the second drive module, the first data write module also serves as the second data write module, the first threshold compensation module also serves as the second threshold compensation module, and the first initialization module also serves as the third initialization module.

18. The display panel according to claim 17, wherein the first drive module comprises a first transistor, the first light emission control module comprises a second transistor and a third transistor, the second light emission control module comprises a fourth transistor and a fifth transistor, the first initialization module comprises a sixth transistor, the second initialization module comprises a seventh transistor, the fourth initialization module comprises an eighth transistor, the first data write module comprises a ninth transistor, and the first threshold compensation module comprises a tenth transistor; and
a first terminal of the second transistor and a first terminal of the fourth transistor are each connected to a first power voltage terminal, a second terminal of the second transistor and a second terminal of the fourth transistor are each connected to a first terminal of the first transistor, the first terminal of the third transistor and a first terminal of the fifth transistor are each connected to a second terminal of the first transistor, a control terminal of the second transistor and a control terminal of the third transistor are each connected to a first light emission control signal terminal, a control terminal of the fourth transistor and a control terminal of the fifth transistor are each connected to a second light emission control terminal, a second terminal of the third transistor is connected to a first electrode of the first light-emitting device, a second terminal of the fifth transistor is connected to a first electrode of the second light-emitting device, a second electrode of the first light-emitting device and a second electrode of the second light-emitting device are each connected to a second power voltage terminal, a control terminal of the sixth transistor is connected to a first scan signal line, a first terminal of the sixth transistor is connected to a reference power signal terminal, a second terminal of the sixth transistor is connected to a control terminal of the first transistor, a control terminal of the tenth transistor is connected to a second scan signal line, a first terminal of the tenth transistor is connected to the second terminal of the first transistor, a second terminal of the tenth transistor is connected to the control terminal of the first transistor, a first terminal of the ninth transistor is connected to a data signal terminal, a second terminal of the ninth transistor is connected to the first terminal of the first transistor, a control terminal of the ninth transistor is connected to the second scan signal line, a first terminal of the seventh transistor is connected to a reference voltage signal terminal, a second terminal of the seventh transistor is connected to the first electrode of the first light-emitting device, a first terminal of the eighth transistor is connected to the second terminal of the seventh transistor, a second terminal of the eighth transistor is connected to the first electrode of the second light-emitting device, and a control terminal of the seventh transistor and a control terminal of the eighth transistor are each connected to the first scan signal line.

19. The display panel according to claim 1, wherein display regions of the display panel comprise a first display region and a second display region, and the first display region comprises a plurality of light-transmissive regions; and
in the first display region, a first-band color pixel of the first-band color pixels comprises one light-emitting device and a light emission color resist.

20. A display device, comprising a display panel, wherein the display panel comprises first-band color pixels and a color resist layer;
wherein one of the first-band color pixels comprises at least two light-emitting devices emitting light of a same color; and
the color resist layer comprises first-band light emission color resists corresponding to the first-band color pixels, wherein a first-band light emission color resist of the first-band light emission color resists comprises at least two sub-color resists transmitting light of different central wavelengths.
